(19) United States
(12) Patent Application Publication
(10) Pub. No.: US 2025/0119146 A1
(43) Pub. Date: Apr. 10, 2025

(54) FREQUENCY DIVIDER CIRCUIT

(71) Applicant: STMicroelectronics International N.V., Geneva (CH)

(72) Inventors: Frederic Rivoirard, Montferrat (FR); Gregoire Lefevre, Grenoble (FR)

(21) Appl. No.: 18/905,501

(22) Filed: Oct. 3, 2024

(30) Foreign Application Priority Data
Oct. 4, 2023 (FR) 2310585

(51) Int. Cl. H03K 21/08; H03K 5/02

(52) U.S. Cl. CPC H03K 21/08; H03K 5/02

(57) ABSTRACT

The present description relates to a frequency divider circuit comprising a first latch, a first output amplifier having at least one input coupled to at least one output of the first latch, a second latch having at least one input coupled to at least one output of the first output amplifier, and a second output amplifier having at least one input coupled to at least one output of the second latch, and having at least one output coupled to an input of the first latch.

### CROSS REFERENCE TO RELATED APPLICATIONS

This application claims the priority benefit of French Patent Application No. 2310585, filed on Oct. 4, 2023, entitled “Circuit diviseur de fréquence,” which is hereby incorporated herein by reference to the maximum extent allowable by law.

### TECHNICAL FIELD

The present disclosure generally concerns electronic circuits and devices, and, more particularly, circuits and devices adapted to processing radio frequency signals. The present disclosure more precisely concerns a frequency divider circuit.

### BACKGROUND

Radio frequency signals currently have a very large number of uses, such as radio communication, systems for detecting the presence and/or the speed of objects, certain medical devices, household appliances, etc.

For this purpose, it may be useful to apply operations to these radio frequency signals, such as, for example, operations concerning the frequency of a radio frequency signal.

It would be desirable to be able to improve, at least partly, certain aspects of known electronic systems adapted to applying operations to one or a plurality of radio frequency signals.

### SUMMARY

There exists a need for electronic systems and devices adapted to more efficiently applying operations to radio frequency signals.

There exists a need for more efficient frequency divider circuits receiving radio frequency signals.

There exists a need for frequency divider circuits receiving radio frequency signals having a better output amplitude.

There exists a need for frequency divider circuits receiving radio frequency signals having an attenuated phase noise.

An embodiment overcomes all or part of the disadvantages of known electronic devices adapted to applying operations to radio frequency signals.

An embodiment overcomes all or part of disadvantages of known frequency divider circuits receiving radio frequency signals.

An embodiment provides a frequency divider circuit comprising a first latch, a first output amplifier having at least one input coupled to at least one output of the first latch, a second latch having at least one input coupled to at least one output of the first output amplifier, and a second output amplifier having at least one input coupled to at least one output of the second latch, and having at least one output coupled to an input of the first latch.

According to an embodiment, the circuit further comprises a first capacitor having a terminal coupled to at least one output of the first output amplifier.

According to an embodiment, the circuit further comprises a second capacitor having a terminal coupled to at least one output of the second output amplifier.

According to an embodiment, the circuit is adapted to receiving a first signal.

According to an embodiment, the first latch comprises at least one clock terminal adapted to receiving the first signal.

According to an embodiment, the second latch comprises at least one clock terminal adapted to receiving the first signal.

According to an embodiment, the first signal is a radio frequency signal.

According to an embodiment, the circuit is adapted to dividing the frequency of the first signal by two.

According to an embodiment, the first latch, the second latch, the first output amplifier, and the second output amplifier are powered with a same power supply voltage.

According to an embodiment, the first latch, the second latch, the first output amplifier, and the second output amplifier receive a same reference voltage.

According to an embodiment, the reference voltage is the ground.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 very schematically shows in the form of blocks an embodiment of a frequency divider circuit;

FIG. 2 partially shows in the form of blocks an electric diagram of the embodiment of a frequency divider circuit of FIG. 1;

FIG. 3 shows an electric diagram of a latch of the embodiment of FIG. 2;

FIG. 4 shows an electric diagram of an output amplifier of the embodiment of FIG. 2;

FIG. 5 partially shows in the form of blocks an electric diagram of a variant of the embodiment of a frequency divider circuit of FIG. 2; and

FIG. 6 shows an electric diagram of a latch of the embodiment of FIG. 5.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

In the rest of the disclosure, there is called radio frequency signal, or RF signal, a periodic electromagnetic signal having a frequency in the range from 3 kHz to 300 GHz.

The embodiments described hereafter concern a circuit adapted to processing radio frequency signals, and in particular a frequency divider circuit adapted to receiving a radio frequency signal as an input, in order to deliver, as an output, two radio frequency signals having a frequency equal to a fraction of the frequency of the input signal. The case studied herein is more precisely a frequency divider circuit adapted to dividing the frequency of an input signal by two.

A frequency divider circuit is generally associated with output amplifiers enabling to amplify the output signals. However, these associations often have too low output amplitudes and having an impact on the phase noise of the circuits downstream of the frequency divider circuit. The embodiments described hereafter improve the output amplitudes and decrease the phase noise of output signals.

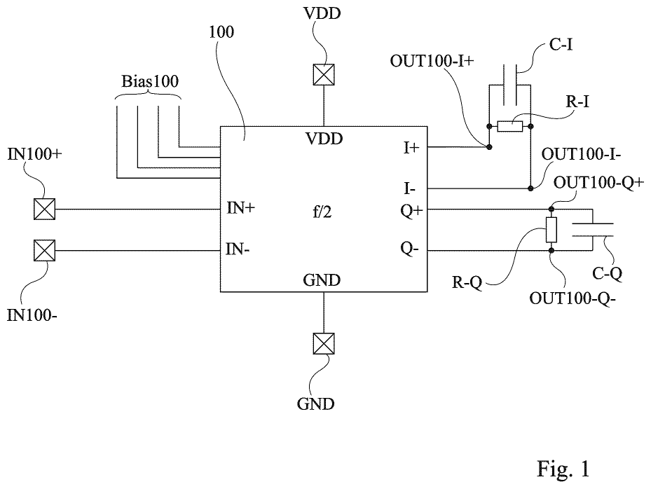

For this purpose, the embodiments described hereafter concern a frequency divider circuit having the output amplifiers directly integrated thereto. Two embodiments of such circuits are described in relation with FIGS. 1, 2, and 5.

FIG. 1 very schematically shows in the form of blocks an embodiment of a frequency divider circuit 100 (f/2).

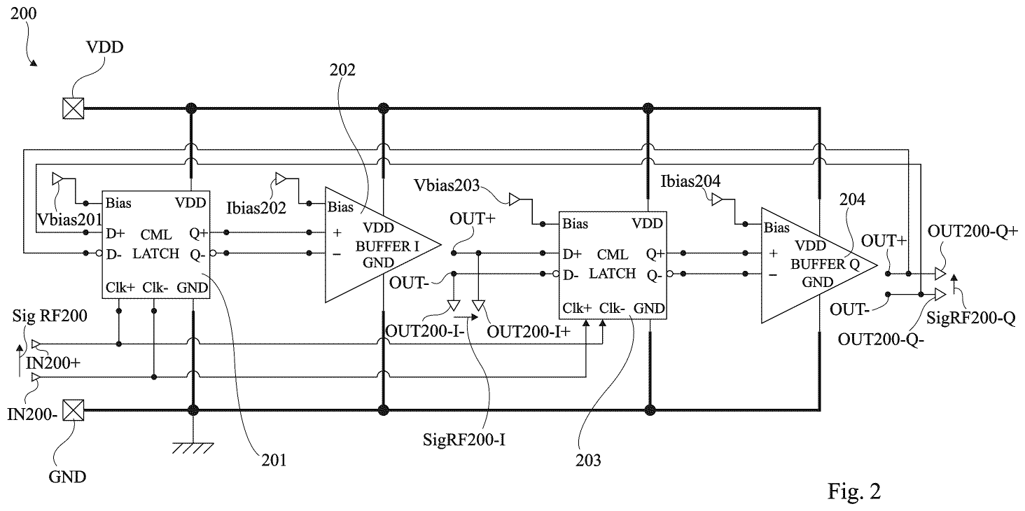

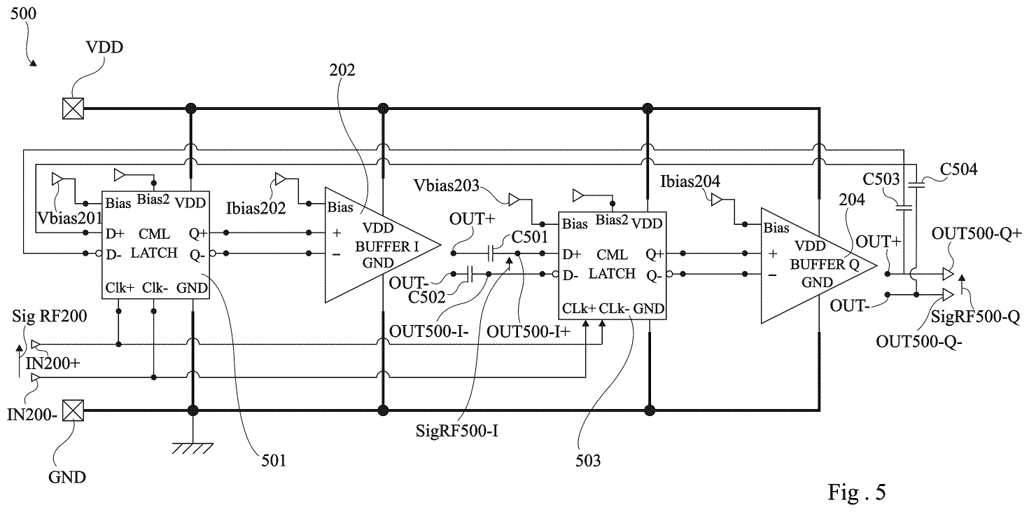

As previously described, frequency divider circuit 100 is formed of the elements of a frequency divider circuit and of two output amplifiers. Two detailed examples of circuit 100 are described in relation with FIGS. 2 and 5.

Circuit 100 comprises two input terminals IN+ and IN− between which an input signal is applied. More particularly, the two input terminals IN+ and IN− are coupled to input nodes IN100+ and IN100− adapted to receiving a radio frequency input signal having a frequency f.

Circuit 100 further comprises four output terminals I+, I−, Q+, and Q− delivering the output signals in phase quadrature (I, Q) of circuit 100. More particularly, the two output terminals I+ and I− are coupled to output nodes OUT100-I+ and OUT100-I− adapted to delivering an output radio frequency signal having a frequency f/2. The two output terminals Q+ and Q− are coupled to output nodes OUT100-Q+ and OUT100-Q− adapted to delivering an output radio frequency signal having a frequency f/2 corresponding to the input signal in quadrature.

Output loads are shown in FIG. 1 by circuits of parallel RC type, that is, circuits comprising a resistor assembled in parallel with a capacitor. More particularly, the output load at output nodes OUT100-I+ and OUT100-I− comprises a resistor R-I coupled between nodes OUT100-I+ and OUT100-I−, and a capacitor C-I coupled between nodes OUT100-I+ and OUT100-I−. Similarly, the output load at output nodes OUT100-Q+ and OUT100-Q− comprises a resistor R-Q coupled between nodes OUT100-Q+ and OUT100-Q−, and a capacitor C-Q coupled between nodes OUT100-Q+ and OUT100-Q−.

Circuit 100 further comprises two power supply terminals VDD and GND. Power supply terminal VDD is adapted to receiving a power supply voltage VDD. Power supply terminal GND is adapted to receiving a reference voltage GND, for example the ground.

Circuit 100 further comprises terminals receiving bias currents and voltages Bias100. These bias currents and voltages are described in further detail in relation with FIG. 2.

FIG. 2 partially shows in the form of blocks an embodiment of a frequency divider circuit 200 of the type of the circuit 100 described in relation with FIG. 1.

As previously described, frequency divider circuit 200 comprises two input terminals IN200+ and IN200− adapted to receiving a radio frequency input signal SigRF200. Circuit 200 further comprises two first output terminals OUT200-I+ and OUT200-I− adapted to delivering a first output signal SigRF200-I having a frequency equal to half the frequency of input signal SigRF200. Circuit 200 further comprises two second output terminals OUT200-Q+ and OUT200-Q− adapted to delivering a second output signal SigRF200-Q in phase quadrature with first output signal SigRF200-I. Circuit 200 further receives power supply voltage VDD and reference voltage GND.

Frequency divider circuit 200 comprises a latch 201 (CML LATCH), an output amplifier 202 (BUFFER I), a latch 203 (CML LATCH), and an output amplifier 204 (BUFFER Q).

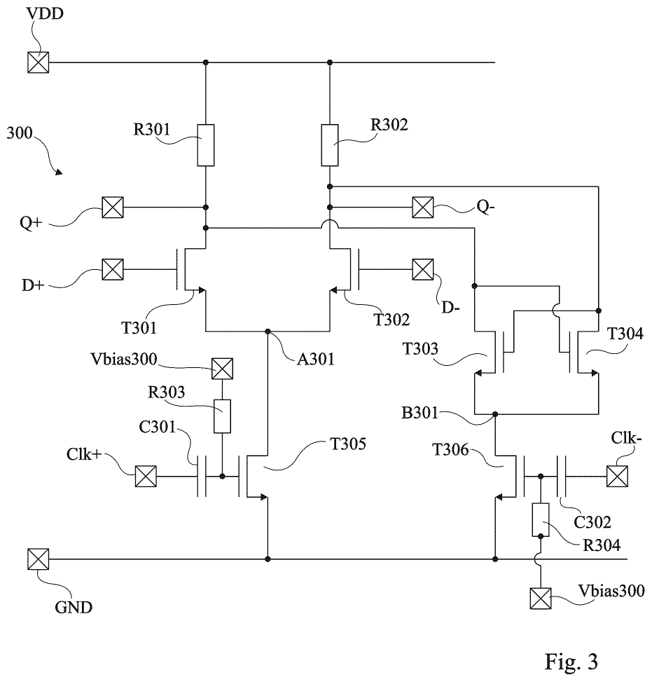

Latches 201 and 203 are latches of CML (Current Mode Logic) type, or current-mode logic latches. A detailed example of latches 201 and 203 is described in relation with FIG. 3. Latches 201 and 203 each have the following terminals: two input terminals D+and D−, two output terminals Q+ and Q−, two clock terminals Clk+ and Clk−, one bias terminal Bias; and two power supply terminals VDD and GND.

The clock terminals Clk+ and Clk− of latches 201 and 203 receive radio frequency input signal SigRF200.

The bias terminal Bias of latch 201 receives a bias voltage Vbias201. The bias terminal Bias of latch 203 receives a bias voltage Vbias203. According to an example, bias voltages Vbias201 and Vbias203 are identical and are delivered by a current mirror, not shown in FIG. 2.

The power supply terminals VDD of latches 201 and 203 both receive power supply voltage VDD. Similarly, the power supply terminals GND of latches 201 and 203 both receive reference voltage GND.

Output amplifiers 202 and 204 each have the following terminals: two input terminals + and −, two output terminals OUT+ and OUT−, one bias terminal Bias, and two power supply terminals VDD and GND.

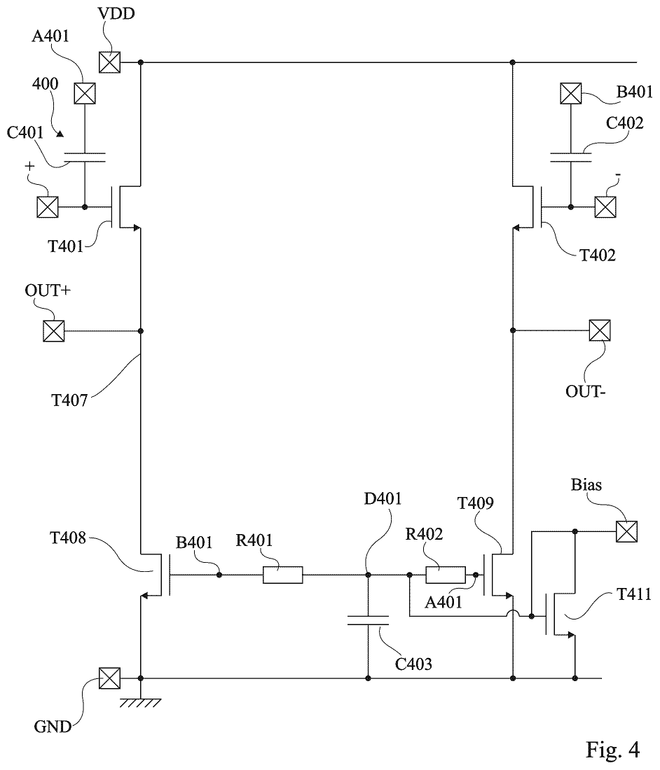

A detailed example of amplifiers 202 and 204 is described in relation with FIG. 4.

The bias terminal Bias of amplifier 202 receives a bias current Ibias202. The bias terminal Bias of amplifier 204 receives a bias current Ibias204. According to an example, bias currents Ibias202 and Ibias204 are identical.

The power supply terminals VDD of amplifiers 202 and 204 both receive power supply voltage VDD. Similarly, the power supply terminals GND of amplifiers 202 and 204 both receive reference voltage GND.

According to an embodiment, the output terminals Q+ and Q− of latch 201 are coupled, preferably connected, to the + and − input terminals of output amplifier 202. In other words, the output terminal Q+ of latch 201 is coupled, preferably connected, to the + input terminal of output amplifier 202, and the output terminal Q− of latch 201 is coupled, preferably connected, to the − input terminal of output amplifier 202.

According to an embodiment, the output terminals OUT+ and OUT− of output amplifier 202 deliver first output signal SigRF200-I, but are also coupled, preferably connected, to the input terminals D+ and D− of latch 203. In other words, the output terminal OUT+ of amplifier 202 is coupled, preferably connected, to the input terminal D+ of latch 203, the output terminal OUT− of amplifier 202 is coupled, preferably connected, to the input terminal D− of latch 203.

According to an embodiment, the output terminals Q+ and Q− of latch 203 are coupled, preferably connected, to the + and − input terminals of output amplifier 204. In other words, the output terminal Q+ of latch 203 is coupled, preferably connected, to the + input terminal of output amplifier 204, and the output terminal Q− of latch 203 is coupled, preferably connected, to the − input terminal of output amplifier 204.

According to an embodiment, the output terminals OUT+ and OUT− of output amplifier 204 deliver the second output signal SigRF200-Q, but are also coupled, preferably connected, to the input terminals D+ and D− of latch 201. In other words, the output terminal OUT+ of amplifier 204 is coupled, preferably connected, to the input terminal D+ of latch 201, the output terminal OUT− of amplifier 204 is coupled, preferably connected, to the input terminal D− of latch 201.

An advantage of the embodiment is that by integrating output amplifiers 202 and 204 to the loop formed by latches 201 and 203, circuit 200 has a lower output impedance. In other words, output signals SigRF200-I and SigRF200-Q have a higher amplitude, which decreases the phase noise of the circuits downstream of circuit 200.

FIG. 3 shows a practical example of a latch 300 of the type of the latches 201 and 203 described in relation with FIG. 2.

According to an example, latch 300 is formed of metal-oxide-semiconductor field-effect transistors, or MOSFET transistors, or MOS transistors. Further, latch 300 is formed of N-channel MOS transistors, or N-type MOS transistors, or NMOS transistors. It will be within the abilities of those skilled in the art to readily adapt the circuits forming latch 300 to use P-channel MOS transistors, or P-type MOS transistors, or PMOS transistors.

Like latches 201 and 203, latch 300 comprises the following terminals: two input terminals D+ and D−, two output terminals Q+ and Q−, two clock terminals Clk+ and Clk−, and two power supply terminals VDD and GND.

Latch 300 comprises two transistors NMOS T301 and T302 having their gates coupled to the input terminals D+ and D− of latch 300. More particularly, the gate of transistor T301 is coupled, preferably connected, to input terminal D+, and the gate of transistor T302 is coupled, preferably connected, to input terminal D−. The sources of transistors T301 and T302 are coupled, preferably connected, together and to a node A301. The drain of transistor T301 is coupled, preferably connected, to the output terminal Q+ of latch 300. The drain of transistor T302 is coupled, preferably connected, to the output terminal Q− of latch 300.

Latch 300 further comprises two resistors R301 and R302 coupling output terminals Q+ and Q− to power supply terminal VDD. More particularly, a first terminal of resistor R301 is coupled, preferably connected, to output terminal Q+, and a second terminal of resistor R301 is coupled, preferably connected, to power supply terminal VDD. Similarly, a first terminal of resistor R302 is coupled, preferably connected, to output terminal Q−, and a second terminal of resistor R302 is coupled, preferably connected, to power supply terminal VDD.

Latch 300 further comprises two NMOS transistors T303 and T304 having their drains and their gates are coupled to output terminals Q+ and Q−. More particularly, the drain of transistor T303 and the gate of transistor T304 are coupled, preferably connected, together and to output terminal Q+. The drain of transistor T304 and the gate of transistor T303 are coupled, preferably connected, together and to output terminal Q−. Further, the sources of transistors T303 and T304 are coupled, preferably connected, together and to node B301.

Latch 300 further comprises an NMOS transistor T305 and a capacitor C301 coupled to clock terminal Clk+. More particularly, a first terminal of capacitor C301 is coupled, preferably connected, to clock terminal Clk+, and a second terminal of capacitor C301 is coupled, preferably connected, to the gate of transistor T305. The drain of transistor T305 is coupled, preferably connected, to node A301, and the source of transistor T305 is coupled, preferably connected, to power supply terminal GND.

Latch 300 further comprises a resistor R303 coupling the gate of transistor T305 to a node delivering a bias voltage Vbias300. More particularly, a first terminal of resistor R303 is coupled, preferably connected, to the gate terminal of transistor T305, and a second terminal of resistor R303 is coupled, preferably connected, to the node delivering bias voltage Vbias300.

Latch 300 further comprises an NMOS transistor T306 and a capacitor C302 coupled to clock terminal Clk−. More particularly, a first terminal of capacitor C302 is coupled, preferably connected, to clock terminal Clk−, and a second terminal of capacitor C302 is coupled, preferably connected, to the gate of transistor T306. The drain of transistor T306 is coupled, preferably connected, to node B301, and the source of transistor T306 is coupled, preferably connected, to power supply terminal GND.

Latch 300 further comprises a resistor R304 coupling the gate of transistor T306 to a node delivering bias voltage Vbias300. More particularly, a first terminal of resistor R304 is coupled, preferably connected, to the gate terminal of transistor T306, and a second terminal of resistor R304 is coupled, preferably connected, to the node delivering bias voltage Vbias300.

FIG. 4 shows a practical example of an output amplifier 400 of the type of the output amplifiers 202 and 204 described in relation with FIG. 2.

According to an example, amplifier 400 is formed of MOS transistors, and more precisely of NMOS transistors. It will be within the abilities of those skilled in the art to readily adapt the circuits forming amplifier 400 to use PMOS transistors.

Like amplifiers 202 and 204, amplifier 400 comprises the following terminals: two input terminals + and −, two output terminals OUT+ and OUT−, one bias terminal Bias, and two power supply terminals VDD and GND.

Output amplifier 400 comprises two transistors NMOS T401 and T402 having their gates coupled to the + and − input terminals of amplifier 400. More particularly, the gate of transistor T401 is coupled, preferably connected, to the + input terminal, and the gate of transistor T402 is coupled, preferably connected, to the − input terminal. The drains of transistors T401 and T402 are coupled, preferably connected, together and to power supply terminal VDD. The source of transistor T401 is coupled, preferably connected, to the output terminal OUT+ of amplifier 400. The source of transistor T402 is coupled, preferably connected, to the output terminal OUT− of amplifier 400.

Amplifier 400 further comprises a capacitor C401 coupling the gate terminal of transistor T401 to a node A401. More particularly, a first terminal of capacitor C401 is coupled, preferably connected, to the gate terminal of transistor T401, that is, to the + input terminal, and a second terminal of capacitor C401 is coupled, preferably connected, to node A401.

Amplifier 400 further comprises a capacitor C402 coupling the gate terminal of transistor T401 to a node B401. More particularly, a first terminal of capacitor C402 is coupled, preferably connected, to the gate terminal of transistor T402, that is, to the − input terminal, and a second terminal of capacitor C402 is coupled, preferably connected, to node B401.

Amplifier 400 further comprises NMOS transistors T408 and T409 forming a current mirror forming a current source of amplifier 400. The drain of transistor T408 is coupled, preferably connected, to output terminal OUT+, and the source of transistor T408 is coupled, preferably connected, to terminal GND. The drain of transistor T409 is coupled, preferably connected, to output terminal OUT−, and the source of transistor T409 is coupled, preferably connected, to terminal GND. The gate of transistor T408 is coupled, preferably connected, to node B401. The gate of transistor T409 is coupled, preferably connected, to node A401.

Amplifier 400 further comprises two resistors R401 and R402 series-coupled between nodes B401 and A401. More particularly, a first terminal of resistor R401 is coupled, preferably connected, to node B401, and a second terminal of resistor R401 is coupled, preferably connected, to a node D401. A first terminal of resistor R402 is coupled, preferably connected, to node D401, and a second terminal of resistor R402 is coupled, preferably connected, to a node A401.

Amplifier 400 further comprises a capacitor C403, and a transistor T411. Capacitor C403 couples node D401 to terminal GND. A first terminal du capacitor C403 is coupled, preferably connected, to node D401, and a second terminal of capacitor C403 is coupled, preferably connected, to terminal GND. The drain and the gate of transistor T411 are coupled, preferably connected, together and to terminal Bias and to node D401, and the source of transistor T411 is coupled, preferably connected, to terminal GND.

FIG. 5 shows, partially in the form of blocks, another embodiment of a frequency divider circuit 500 of the type of the circuit 100 described in relation with FIG. 1.

Frequency divider circuit 500 is similar to the frequency divider circuit 200 described in relation with FIG. 2. The elements common to circuits 200 and 500 are not described in detail again herein, and only the differences between circuits 200 and 500 are highlighted.

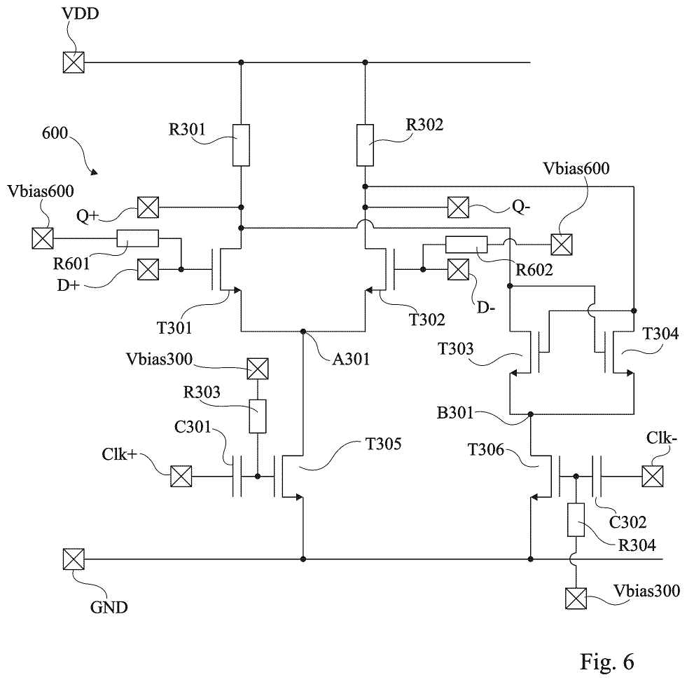

Thus, like circuit 200, circuit 500 comprises latches 501 and 503 and output amplifiers 202 and 204 assembled as described in relation with FIG. 2. Latches 501 and 503 are very similar to the latches 201 and 203 described in relation with FIG. 2, and comprise, in particular, the same connection terminals. Latches 501 and 503 differ from latches 201 and 203 in that they further comprise a terminal Bias2 enabling to apply a second bias voltage. A detailed example of latches 501 and 503 is described in relation with FIG. 6.

Circuit 500 further comprises capacitive output links. For this purpose, circuit 500 comprises capacitors C501, C502, C503, and C504 arranged at the outputs of output amplifiers 202 and 204.

More particularly, circuit 500 further comprises capacitors C501 and C502 coupling the output terminals OUT+ and OUT− of output amplifier 202 to the output nodes OUT500-I+ and OUT500-I− of circuit 500. In other words, a first terminal of capacitor C501 is coupled, preferably connected, to the terminal OUT+ of amplifier 202, and a second terminal of capacitor C501 is coupled, preferably connected, to node OUT500-I+ and to the terminal D+ of latch 503. Similarly, a first terminal of capacitor C502 is coupled, preferably connected, to the terminal OUT− of amplifier 202, and a second terminal of capacitor C502 is coupled, preferably connected, to node OUT500-I− and to the terminal D+ of latch 503.

Similarly, circuit 500 further comprises capacitors C503 and C504 coupling the output terminals OUT+ and OUT− of output amplifier 202 to the output nodes OUT500-Q+ and OUT500-Q− of circuit 500. In other words, a first terminal of capacitor C503 is coupled, preferably connected, to the terminal OUT+ of amplifier 202, and a second terminal of capacitor C503 is coupled, preferably connected, to node OUT500-Q+ and to the terminal D+ of latch 501. Similarly, a first terminal of capacitor C504 is coupled, preferably connected, to the terminal OUT− of amplifier 202, and a second terminal of capacitor C504 is coupled, preferably connected, to node OUT500-Q− and to the terminal D− of latch 501.

FIG. 6 shows a practical example of a latch 600 of the type of the latches 501 and 503 described in relation with FIG. 2.

Latch 600 is similar to the latch 300 described in relation with FIG. 3. The elements common to circuits 300 and 600 are not described in detail again herein, and only the differences between circuits 300 and 600 are highlighted.

Thus, like latch 300, latch 600 comprises transistors T301 to T306, resistors R301 to R304, and capacitors C301 and C302 arranged as described in relation with FIG. 3.

Latch 600 further comprises bias resistors R601 and R602 enabling to bias the gates of transistors T301 and T302. More particularly, resistor R301 comprises a first terminal coupled, preferably connected, to the gate terminal of transistor T301 and a second terminal coupled, preferably connected, to a node delivering a bias voltage Vbias600. Resistors R302 comprises a first terminal coupled, preferably connected, to the gate terminal of transistor T302 and a second terminal coupled, preferably connected, to the node delivering bias voltage Vbias600. According to an example, bias voltage Vbias600 is different from bias voltage Vbias300. According to an example, bias voltage Vbias600 is controlled by a control loop (not shown in FIG. 6) used to control the voltages applied on terminals D− and D+.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A frequency divider circuit comprising:
a first latch;
a first output amplifier having at least one input coupled to at least one output of the first latch;
a second latch having at least one input coupled to at least one output of the first output amplifier;
a second output amplifier having at least one input coupled to at least one output of the second latch, and having at least one output coupled to at least one input of the first latch.

2. The frequency divider circuit according to claim 1, further comprising a first capacitor coupled between the at least one output of the first output amplifier and the at least one input of the second latch.

3. The frequency divider circuit according to claim 1, further comprising a second capacitor coupled between the at least one output of the second output amplifier and the at least one input of the first latch.

4. The frequency divider circuit according to claim 1, wherein the frequency divider circuit is configured to receive a first signal.

5. The frequency divider circuit according to claim 4, wherein the first latch comprises at least one clock terminal configured to receiving the first signal.

6. The frequency divider circuit according to claim 5, wherein the second latch comprises at least one clock terminal configured to receive the first signal.

7. The frequency divider circuit according to claims 4, wherein the first signal is a radio frequency signal.

8. The frequency divider circuit according to claim 4, wherein the frequency divider circuit is configured to divide a frequency of the first signal by two.

9. The frequency divider circuit according to claim 1, wherein the first latch, the second latch, the first output amplifier, and the second output amplifier are powered with a same power supply voltage.

10. The frequency divider circuit according to claim 9, wherein the first latch, the second latch, the first output amplifier, and the second output amplifier receive a same reference voltage.

11. The frequency divider circuit according to claim 10, wherein the reference voltage is ground.

12. A frequency divider circuit comprising:
a first latch;
a first output amplifier having first and second inputs respectively coupled to first and second outputs of the first latch;
a second latch having first and second inputs respectively coupled to first and second outputs of the first output amplifier; and
a second output amplifier having first and second inputs respectively coupled to first and second outputs of the second latch, and having first and second outputs respectively coupled to first and second inputs of the first latch.

13. The frequency divider circuit according to claim 12, further comprising:
a first capacitor coupled between the first output of the first output amplifier and the first input of the second latch; and
a second capacitor coupled between the second output of the first output amplifier and the second input of the second latch.

14. The frequency divider circuit according to claim 12, further comprising:
a third capacitor coupled between the first output of the second output amplifier and the first input of the first latch; and
a fourth capacitor coupled between the second output of the second output amplifier and the second input of the first latch.

15. The frequency divider circuit according to claim 12, wherein the frequency divider circuit is configured to receive + and − components of a first signal.

16. The frequency divider circuit according to claim 15, wherein the first latch comprises first and second clock terminals respectively configured to receive the + and − components of the first signal.

17. The frequency divider circuit according to claim 16, wherein the second latch comprises first and second clock terminals respectively configured to receive the + and − components of the first signal.

18. The frequency divider circuit according to claim 15, wherein the first signal is a radio frequency signal.

19. The frequency divider circuit according to claim 15, wherein the frequency divider circuit is configured to divide a frequency of the first and second signals by two.

20. The frequency divider circuit according to claim 12, wherein the first latch, the second latch, the first output amplifier, and the second output amplifier are powered with a same power supply voltage.

21. The frequency divider circuit according to claim 20, wherein the first latch, the second latch, the first output amplifier, and the second output amplifier receive a same reference voltage.

22. The frequency divider circuit according to claim 21, wherein the reference voltage is ground.
